(19) United States
(12) Patent Application Publication
(10) Pub. No.: US 2024/0283452 A1
(43) Pub. Date: Aug. 22, 2024

(54) METHOD AND SYSTEM FOR PROVIDING A COMPOSITE OF CIRCUITRY AND FABRIC

(71) Applicant: HTI Technology and Industries, Inc., Peabody, MA (US)

(72) Inventors: John Simonetti, Lynnfield, MA (US); Steve Sweeney, Beverly, MA (US)

(73) Assignee: HTI Technology and Industries, Inc., Peabody, MA (US)

(21) Appl. No.: 18/441,295

(22) Filed: Feb. 14, 2024

Related U.S. Application Data
(60) Provisional application No. 63/485,505, filed on Feb. 16, 2023.

(51) Int. Cl. H03K 17/96; G01D 5/24; H05K 1/03; H05K 1/09

(52) U.S. Cl. CPC H03K 17/962; G01D 5/24; H05K 1/038; H05K 1/092

(57) ABSTRACT

Provided is a circuit system that connects capacitive sensors via clear ink to controllers for controlling certain functions. The circuit system may be adhered, printed, or embedded in fabric, thermoplastic olefin, or leather. The capacitive sensors may be illuminated by Light Emitting Diodes (LEDs).

### CROSS-REFERENCE TO RELATED APPLICATIONS

This application claims the benefit of U.S. Provisional Application No. 63/485,505, entitled METHOD AND SYSTEM FOR PROVIDING A COMPOSITE OF CIRCUITRY AND FABRIC, filed Feb. 16, 2023, which is fully incorporated herein by reference.

### I. BACKGROUND

This disclosure is directed to a circuit system comprising translucent or opaque conductive ink and one or more capacitive sensors. The circuit system is adhered, printed, or embedded on or in fabric.

### II. SUMMARY OF THE INVENTION

In accordance with one aspect of this disclosure, provided is a control system of a vehicle, including a user interface component configured on a user-accessible portion of the vehicle. A circuit system is configured onto the user interface. The circuit system includes a circuit trace of a translucent or opaque conductive ink layer applied onto a flexible substrate affixed to the user interface component. One or more capacitive sensors are provided in electrical connection with the circuit system via the circuit trace. The capacitive sensor is actuated by user contact. A controller is provided in electrical connection with the circuit system and operable by the capacitive sensor(s) to regulate the operation of an electrical component.

In one aspect, the user-accessible portion comprises a vehicle arm rest, where the circuit system is formed onto the arm rest. The flexible substrate can be a vehicle interior material selected from one or more of fabric, thermoplastic olefin, or leather.

A plurality of capacitive sensors can be provided on the user interface component for regulating respective operations of a respective plurality of electrical components. The circuit trace is formed by any suitable method, including adhering, printing or embedding the translucent or opaque conductive ink onto or into the fabric. The capacitive sensor(s) can include one or more light emitting diodes (LEDs) for illuminating the capacitive sensor to indicate actuation by user contact.

In another aspect, the electrical component can include one or more LEDs, the operation of which is regulated by the controller. The electrical component can be a vehicle HVAC system such that the capacitive sensor is configured to direct the controller to raise or lower a temperature of air emitted inside the vehicle. The electrical component can include a vehicle power window system such that the at least one capacitive sensor is configured to direct the controller to raise or lower a window inside the vehicle. The electrical component can include a vehicle audio system such that the capacitive sensor is configured to direct the controller to raise or lower a volume of sound emitted inside the vehicle. The electrical component can include a glovebox closure such that the capacitive sensor is configured to direct the controller to open the glovebox closure. The electrical component can include a vehicle seat position system such that the capacitive sensor is configured to direct the controller to displace a position of a seat inside the vehicle.

In an alternate embodiment of the present invention a control circuit is provided including a circuit system having a circuit trace formed of a conductive ink layer applied onto a fabric, TPU or similar substrate material. A capacitive sensor is in electrical connection with the circuit system via the circuit trace, where the capacitive sensor is actuated by user contact. A controller is provided in electrical connection with the circuit system and operable by the capacitive sensor to regulate the operation of an electrical component.

Still other benefits and advantages of the invention will become apparent to those skilled in the art to which it pertains upon a reading and understanding of the following detailed specification.

### III. BRIEF DESCRIPTION OF THE FIGURES

The disclosure may take physical form in certain parts and arrangement of parts, aspects of which will be described in detail in this specification and illustrated in the accompanying figures which form a part hereof.

FIG. 1 is a plan view diagram of an arm rest in the center of a car that has a circuit system using clear ink in accordance with an exemplary embodiment of the present invention.

FIG. 2 is a plan view depicting an alternative arrangement of a clear structure using the clear ink and a plurality of LEDs in accordance with an alternative exemplary embodiment of the present invention.

FIG. 3 is a schematic of the general components in accordance with an exemplary embodiment of the present invention.

### IV. DETAILED DESCRIPTION

Reference is now made with respect to the figures wherein the showings are for purposes of illustrating aspects of the disclosure only and not for purposes of limiting the same, and wherein like reference numerals are understood to refer to like components.

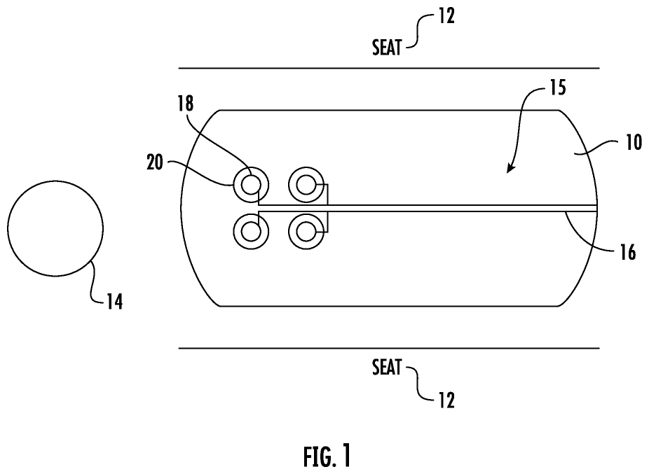

FIG. 1 shows an arm rest 10 in a drive/passenger cabin of a vehicle, arranged between two vehicle seats 12. In front of the arm rest 10 is a cup holder 14. The arm rest 10 can be made of a substrate material selected from leather, fabric, thermoplastic olefin, or other similar material, or some combination of materials. FIG. 1 also shows a circuit system 15 formed onto the arm rest 10. The circuit system 15 can include a translucent or opaque ink layer 16 and one or more capacitance sensors 18. The conductive ink layer 16 can be fabricated with silver nanowire composite ink capable of carrying an electrical current. The ink 16 can be transparent or opaque. The circuit system 15 can formed by adhering, printing, or embedding the clear ink layer 16 onto or into the substrate material including a fabric.

With continued reference to FIG. 1, the arm rest 10 can have a series of capacitance sensors 18. In general, the capacitance sensor 18 can be actuated when a person's hand comes close to the sensor 18. In particular, the capacitance sensor 18 can be utilized for proximity sensing when a person's hand or finger is about 1.5 inches from the sensor 18. Sensor 18 can also be used for activation of specific product functions. The capacitance sensors 18 may be close together as shown in FIG. 1, or they may be significantly separated.

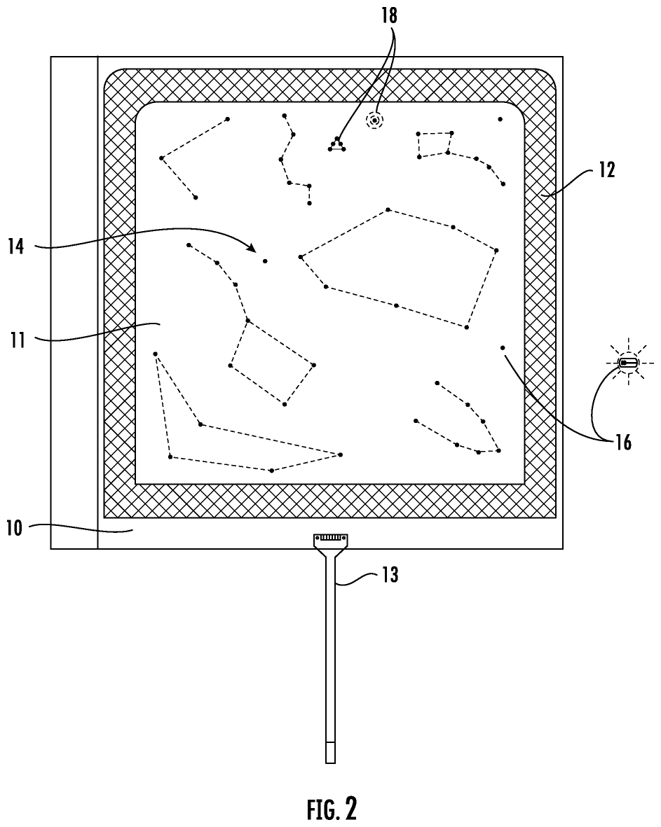

With continued reference to FIG. 1 and also FIG. 2, the circuit system 15 can include one or more LEDs 20. The LEDs 20 can utilize multiple LED manufacturers. Each LED 20 can be controlled by a controller 30 such that when the capacitance sensor 18 is actuated by a user, the LED 20 simultaneously illuminates. Each of the LEDs 20 can be arranged in or on fabric or other material in any selected certain arrangements. For example, each of the LEDs 20 could be arranged so that when they illuminate, they display the logo for an automobile manufacturer.

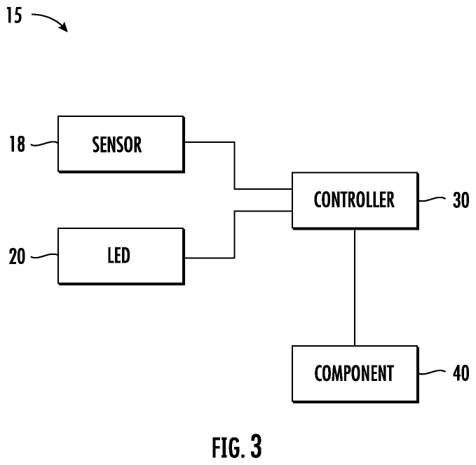

With continued reference to FIGS. 1 and 3, the capacitance sensor 18 can be connected to the controller 30 for controlling certain functions of electrical and/or electronic components 40. In one aspect of this disclosure, when the capacitance sensor 18 is actuated, the controller 40 can direct an electrical component 40 such as an automobile air conditioning system to raise/lower the temperature of air emitting from the air conditioning system. The controller 30 can direct an electrical component 40 such as a vehicle window motor to raise/lower a window. The controller 30 can direct an electrical component 40 such as an automobile sound system to raise/lower the sound volume. The controller 30 can direct an electrical component 40 such as a cup holder heating/cooler system to heat or cool a drink. In another aspect of this disclosure, the circuit system 15 is positioned on an electrical component 40 such as a glovebox compartment. When a person actuates capacitance sensor 18, the controller 40 can unlatch the glovebox so that it may fall open.

With continued reference to FIGS. 1 and 3, in one aspect of this disclosure, the circuit system 15 can be used in the airline context in an airplane. In this aspect, when the capacitance sensor 18 is actuated, the controller 30 can direct an electronic component 40 such as a motor system to adjust the seat's position and arrangement. The controller 30 can direct an electronic component 40 such as an airplane air conditioning system to increase/decrease airflow on the passenger. The controller 30 can direct an electronic component 40 such as an entertainment system to raise/lower the volume of the system. The controller 30 can direct an electronic component 40 such as a video screen to change a program that is displayed in front of the passenger.

In an exemplary embodiment shown in the above figures, the circuit system 11 can be sized approximately 532 mm by 860 mm. It can be populated with 98 LEDs 16 grouped into 18 different circuits. The LED 16 count can vary between 1 to 12 LEDs 16 per circuit with 24 traces in each circuit. The circuits can be laminated between two layers of polyvinyl butyral (PVB) and then laminated between two layers of glass. Of course, it is to be appreciated that other suitable configurations and materials could alternately be employed without departing from the invention.

A method of manufacturing a circuit system adhered, printed, or embedded ono or into includes the following. A circuit system 15 is provided with a translucent or opaque ink layer 16 and one or more capacitance sensors 18. A step is provided of adhering, printing, or embedding the circuit system 15 with the fabric, TPO, or leather.

Numerous embodiments have been described herein. It will be apparent to those skilled in the art that the above methods and apparatuses can incorporate changes and modifications without departing from the general scope of this invention. It is intended to include all such modifications and alterations in so far as they come within the scope of the appended claims or the equivalents thereof.

What is claimed:

1. A control system of a vehicle, comprising:
a user interface component configured on a user-accessible portion of the vehicle;
a circuit system configured onto the user interface, wherein the circuit system comprises a circuit trace fabricated of a translucent or opaque conductive ink layer formed onto a flexible substrate affixed to the user interface component;
at least one capacitive sensor in electrical connection with the circuit system via the circuit trace, wherein the capacitive sensor is actuated by user contact; and
a controller in electrical connection with the circuit system and operable by the at least one capacitive sensor to regulate the operation of an electrical component.

2. The control system of claim 1, wherein the user-accessible portion comprises a vehicle arm rest, and wherein the circuit system is formed onto the arm rest.

3. The control system of claim 1, wherein the at least one capacitive sensor comprises a plurality of capacitive sensors of the user interface component for regulating respective operations of a respective plurality of electrical components.

4. The control system of claim 1, wherein the circuit trace is fabricated by at least one of adhering, printing or embedding the clear or opaque conductive ink onto or into the fabric.

5. The control system of claim 1, wherein the at least one capacitive sensor comprises at least one light emitting diode (LED) for illuminating the capacitive sensor to indicate actuation by user contact.

6. The control system of claim 1, wherein the electrical component comprises at least light emitting diode (LED), the operation of which is regulated by the controller.

7. The control system of claim 1, wherein the electrical component comprises a vehicle HVAC system such that the at least one capacitive sensor is configured to direct the controller to raise or lower a temperature of air emitted inside the vehicle.

8. The control system of claim 1, wherein the electrical component comprises a vehicle power window system such that the at least one capacitive sensor is configured to direct the controller to raise or lower a window inside the vehicle.

9. The control system of claim 1, wherein the electrical component comprises a vehicle audio system such that the at least one capacitive sensor is configured to direct the controller to raise or lower a volume of sound emitted inside the vehicle.

10. The control system of claim 1, wherein the electrical component comprises a glovebox closure such that the at least one capacitive sensor is configured to direct the controller to open the glovebox closure.

11. The control system of claim 1, wherein the electrical component comprises a vehicle seat position system such that the at least one capacitive sensor is configured to direct the controller to displace a position of a seat inside the vehicle.

12. The control system of claim 1, wherein the flexible substrate is a vehicle interior material selected from at least one of fabric, thermoplastic olefin, or leather.

13. A control circuit, comprising:
a circuit system comprising a circuit trace formed of a translucent or opaque conductive ink layer formed onto a fabric;
a capacitive sensor in electrical connection with the circuit system via the circuit trace, wherein the capacitive sensor is actuated by user contact; and
a controller in electrical connection with the circuit system and operable by the capacitive sensor to regulate the operation of an electrical component.
